(19) United States
(12) Patent Application Publication
(10) Pub. No.: US 2004/0214371 A1
(43) Pub. Date: Oct. 28, 2004

(54) System and method for conventional molding using a new design potblock

(76) Inventor: Syed Omar Syed Mahmood, Ampang Selangor (MY)

Correspondence Address: TEXAS INSTRUMENTS INCORPORATED, P O BOX 655474, M/S 3999, DALLAS, TX, 75265

(21) Appl. No.: 10/823,348

(22) Filed: Apr. 12, 2004

Related U.S. Application Data
(60) Provisional application No. 60/465,838, filed on Apr. 25, 2003.

(30) Foreign Application Priority Data
Nov. 6, 2003 (MY) PI20034248

(51) Int. Cl. H01L 21/44

(52) U.S. Cl. 438/106

(57) ABSTRACT

In one embodiment, a mold for forming a molded part includes a baseplate, at least one pot formed in the baseplate for receiving a mold compound, and at least one cavity formed in the baseplate. The cavity is adapted to receive a microelectronic device. The mold also includes at least one channel system formed in the baseplate and coupled to the at least one pot and further coupled to the at least one cavity. The mold further includes at least one first channel formed in the baseplate and coupled to the at least one channel system. The at least one first channel is separated from the at least one cavity by the at least one channel system.

### RELATED APPLICATIONS

This application claims the benefit under 35 U.S.C. § 119(e) of U.S. Provisional Patent Application No. 60/465,838 entitled “Makyung-New Design Potblock for Conventional Molding System” filed Apr. 25, 2003.

### TECHNICAL FIELD OF THE INVENTION

This invention relates generally to molding systems and more particularly to a system and method for conventional molding using a new design potblock.

### BACKGROUND OF THE INVENTION

Semiconductor devices are used in a wide variety of applications. The requirement for cheaper and smaller products initiated the development of new semiconductor packaging technology. A popular form of semiconductor packaging technology includes attaching semiconductor devices to a piece of metal ribbon called a leadframe. Semiconductor devices are attached to the center of the leadframe and are often encapsulated in a material such as an epoxy molding compound. The encapsulation of the semiconductor devices protects the delicate electrical devices from outside elements. In addition, semiconductor encapsulation results in more robust components having an acceptable level of reliability, particularly for consumer applications. However, conventional methods of encapsulation suffer from problems such as the entrapment of air inside the molding compound. Air trapped in the molding compound during encapsulation creates air pockets or voids, which form around the semiconductor devices. These voids will move together with the molding compound during the encapsulation process and disturb the wire connections between the semiconductor devices and the leadframe, causing the wires to move (a condition known as “wire sweep”), which negatively impacts the reliability of the encapsulated components.

A common problem with conventional molding is the inability to adequately remove the air trapped in the molding compound during the molding process. The reduction of internal voids in the molding process is usually accomplished by tightly controlling parameters such as the preheat temperature, the mold compound temperature, and the speed of the transfer of the mold compound inside of the mold. However, these parameters are not easily controlled, as there are complicated interactions between each of the parameters.

### SUMMARY OF THE INVENTION

In one embodiment, a mold for forming a molded part includes a baseplate, at least one pot formed in the baseplate for receiving a mold compound, and at least one cavity formed in the baseplate. The cavity is adapted to receive a microelectronic device. The mold also includes at least one channel system formed in the baseplate and coupled to the at least one pot and further coupled to the at least one cavity. The mold further includes at least one first channel formed in the baseplate and coupled to the at least one channel system. The at least one first channel is separated from the at least one cavity by the at least one channel system.

In another embodiment, a mold for forming a molded part includes a baseplate, at least one pot formed in the baseplate for receiving a mold compound, and at least one sprue channel formed in the baseplate and coupled to the at least one pot. The mold also includes at least one cavity formed in the baseplate and adapted to receive a microelectronic device and at least one runner channel formed in the baseplate. The runner channel couples the at least one sprue channel to the at least one cavity. The mold further includes at least one dummy runner channel formed in the baseplate and coupled to the at least one sprue channel. The at least one dummy runner channel is separated from the at least one cavity by the at least one sprue channel. The mold also includes at least one vent coupled to the at least one dummy runner channel. The at least one vent is adapted to vent air expelled from the mold compound.

In yet another embodiment, a method for forming a molded part includes placing a mold compound into at least one pot of a mold, pushing a portion of the mold compound through at least one sprue channel coupled to the at least one pot, and pushing a portion of the mold compound into at least one dummy runner channel coupled to the at least one sprue channel runner. The at least one dummy runner channel is separated from at least one cavity by the at least one sprue channel. The method also includes venting air expelled from the mold compound through at least one vent coupled to the at least dummy runner channel. The method further includes pushing a portion of the mold compound through at least one runner channel and into the least one cavity adapted to receive a microelectronic device. The at least one runner channel is coupled to the at least one sprue channel and further coupled to the at least one cavity. The method also includes curing the mold compound to form the molded part.

Technical advantages of one or more embodiments of the present invention may include providing a molded part with a reduced number of internal voids in the cured mold compound. Another technical advantage of one embodiment of the present invention is to provide encapsulation of microelectronic components that reduces the occurrence of “wire sweep” and provides for more robust components.

Certain embodiments may provide all, some, or none of these technical advantages. Certain embodiments may provide one or more other technical advantages, one or more of which may be readily apparent to those skilled in the art from the figures, description, and claims included herein.

### BRIEF DESCRIPTION OF THE DRAWINGS

To provide a more complete understanding of the present invention and certain features and advantages thereof, reference is made to the following description taken in conjunction with the accompanying drawings, in which:

FIG. 1A illustrates an isometric view of an example bottom mold including a potblock and chases;

FIG. 1B illustrates an isometric view of an example molded part formed using the bottom mold of FIG. 1A;

FIG. 2 illustrates a schematic diagram after a molding compound is transferred in a top mold's bushing;

FIG. 3A illustrates a schematic view of an example distribution of internal voids formed within the molded part of FIG. 1B;

FIG. 3B illustrates example predicted flow paths of mold compound within the bottom mold of FIG. 1A;

FIG. 4A illustrates an isometric view of an example bottom mold with dummy runner channels according to the teachings of the invention;

FIG. 4B illustrates a plan view of a molded part formed using the bottom mold of FIG. 4A;

FIG. 5 illustrates a cross-sectional view of an example dummy runner channel of the bottom mold of FIG. 4A; and

FIG. 6 illustrates an example method for forming the molded part of FIG. 4B.

### DESCRIPTION OF EXAMPLE EMBODIMENTS

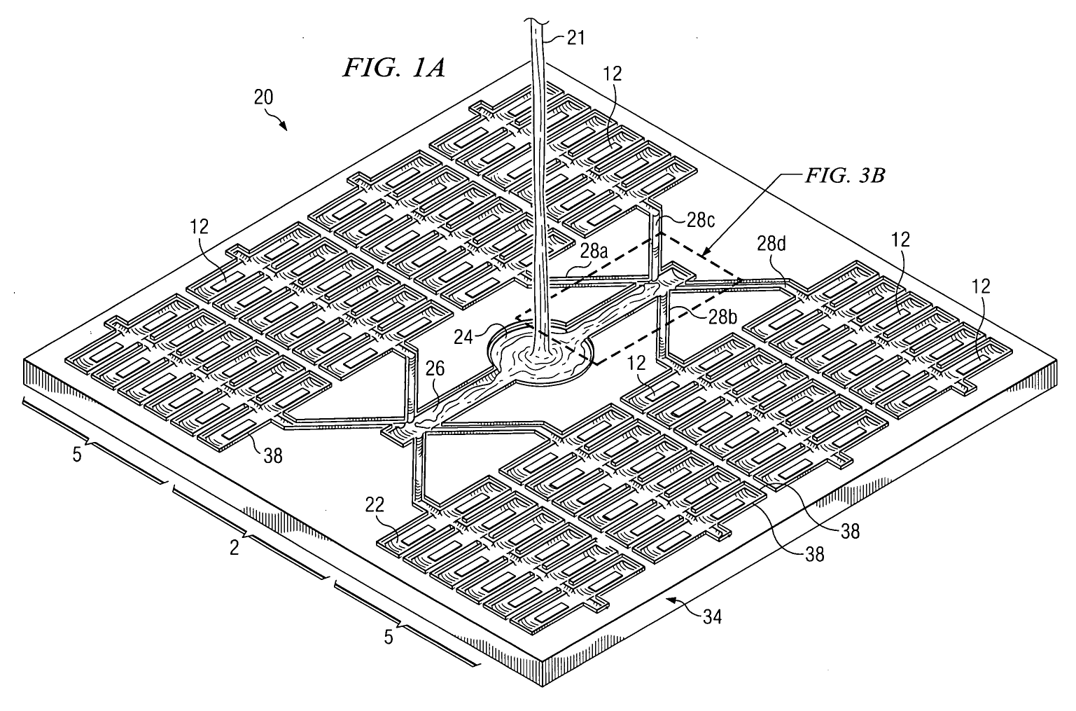

FIG. 1A illustrates an isometric view of an example bottom mold 20 including a potblock 2 and chases 5. In certain embodiments, a mold may include either a bottom mold 20, a top mold 15 (not shown in FIG. 1A for clarity), or both. In the illustrated embodiment, bottom mold 20 includes a baseplate 34 having a plurality of “hollows” 22, 24, 26, and 28 formed therein and bordered by edges 38. Bottom mold 20 may be made from metal or any other appropriate material. In a particular embodiment, these hollows may include cavities 22, a “pot” 24, sprue channels 26, and runner channels 28. Potblock 2 includes pot 24, sprue channels 26, and runner channels 28. Chases 5 include a plurality of interconnected cavities 22. Cavities 22, pot 24, sprue channels 26, and runner channels 28 may each comprise a chamber, well, or other appropriate “hollow” that is adapted to receive and hold mold compound 21. In a particular embodiment, mold compound 21 comprises an epoxy compound.

Pot 24 is the entry point of mold compound 21 into bottom mold 20 and, in effect, forms a reservoir where mold compound 21 begins to flow to the other portions of bottom mold 20, such as sprue channels 26, runner channels 28, and cavities 22. Sprue channels 26 are adapted to provide a pathway for mold compound 21 to flow from pot 24 into runner channels 28. Runner channels 28 are adapted to direct the flow of mold compound 21 into cavities 22. Cavities 22 may be adapted to hold components 12. Components 12 may include, but are not limited to, microelectronic devices, such as semiconductor devices, or any other appropriate components for which encapsulation is desirable. Components 12 may be interconnected to one another using a wire leadframe (not shown in FIG. 1A for clarity).

Mold compound 21 may be pushed through channels 26, 28 into cavities 22 holding components 12 such that mold compound 21 surrounds each component 12. Pressure and temperature may be applied to mold compound 21 during the mold process. As a result of the applied temperature, pressure, and/or the passage of time, mold compound 21 will set, or cure, to produce an encapsulation around component 12 and form a molded part.

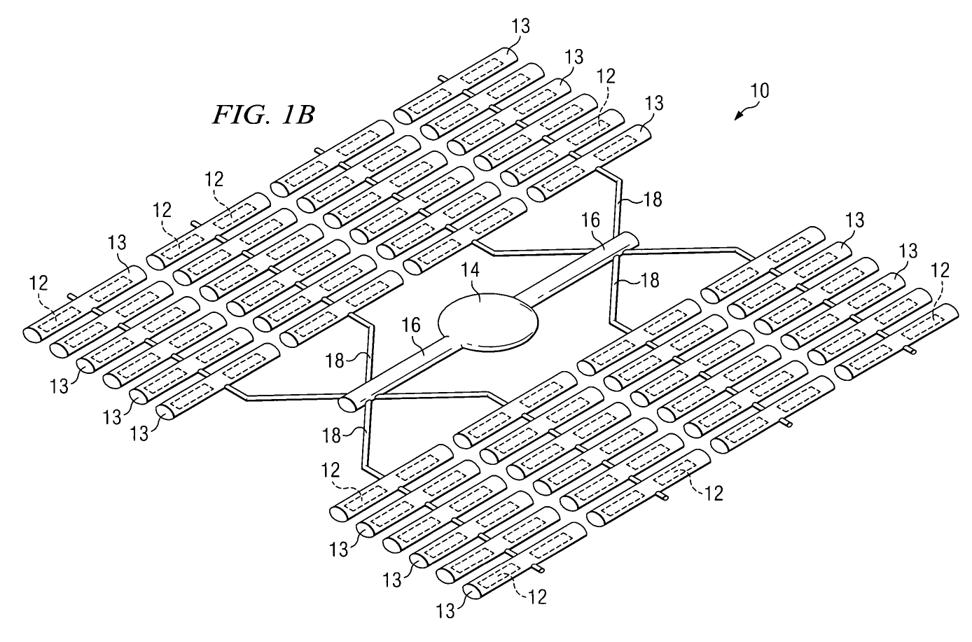

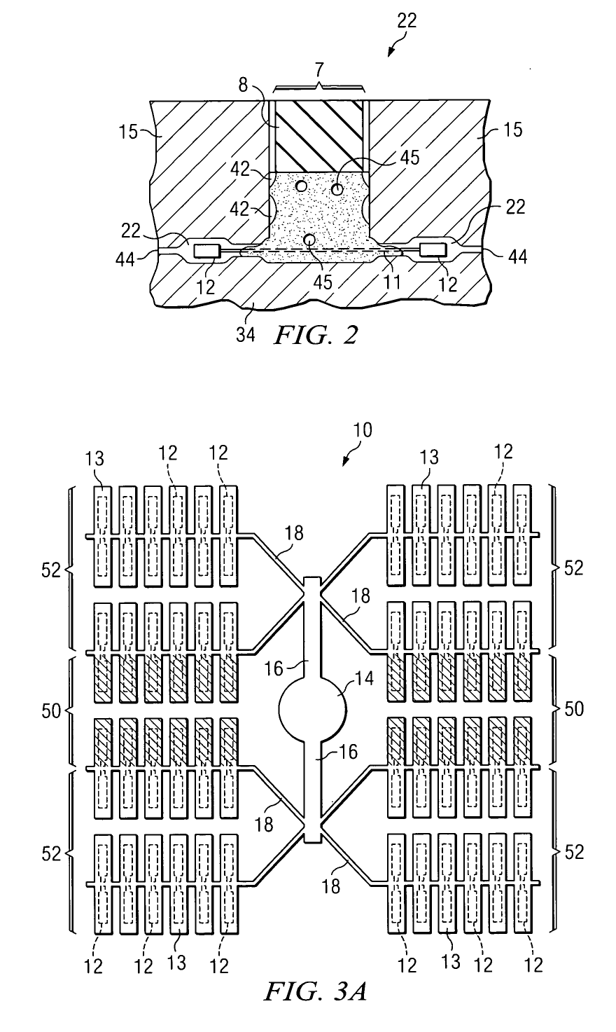

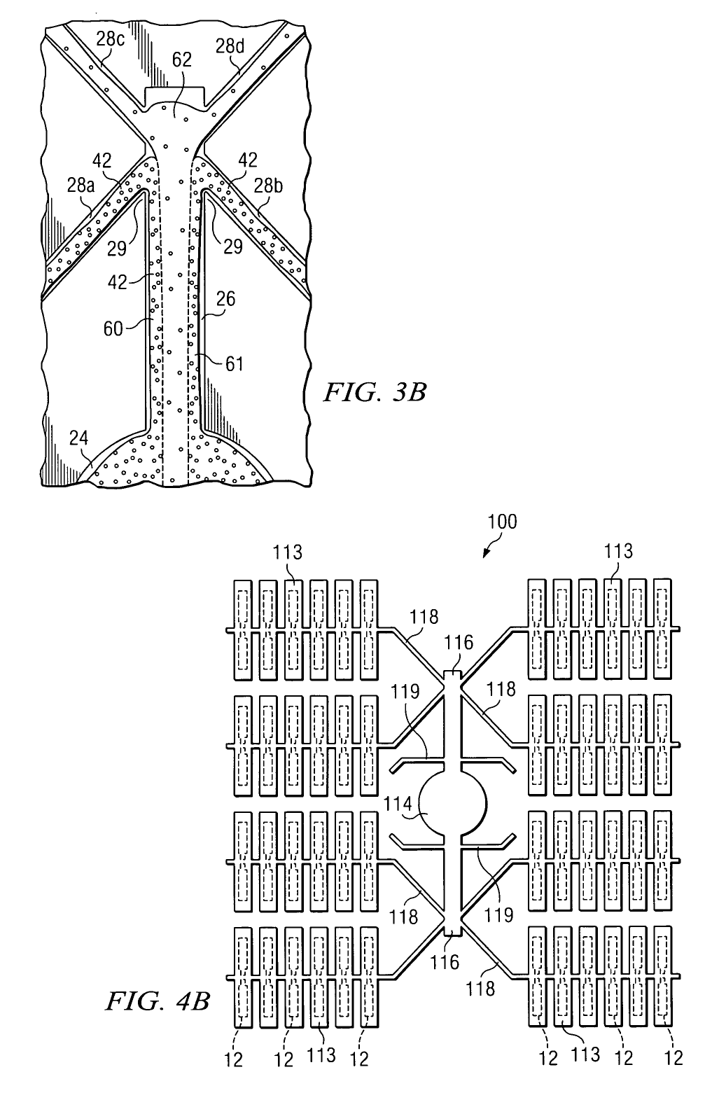

However, during the molding process, air and other gases may become entrapped within the mold compound, leading to the creation internal voids within the molded part, as discussed below with reference to FIGS. 2 through 3B. A robust mold system that has the capability to reduce the number of internal voids generated during the molding process is needed to resolve problems of conventional mold systems, such as those including potblock 2 of bottom mold 20 or other similar potblock configurations. The present invention, as discussed with reference to FIGS. 4A through 6, provides a mold system that may reduce the number of internal voids generated during the molding process.

FIG. 1B illustrates an isometric view of an example molded part 10 formed using bottom mold 20. In certain embodiments, molded part 10 includes encapsulations 13 corresponding to cavities 22. Molded part 10 may also include a cull 14 coupled to sprues 16, which correspond to pot 24 and sprue channels 26, respectively. Runners 18, corresponding to runner channels 28, may be coupled to sprues 16 and encapsulations 13. In general, cull 14, sprues 16, and runners 18 may be discarded after the molding process is completed and molded part 10 is removed from bottom mold 20, as the main objective of the molding process is to produce encapsulations 13.

FIG. 2 illustrates a schematic diagram after molding compound 21 is transferred into a bushing 7 of top mold 15. Plunger 8 is shown “pushing” mold compound 21 through the mold formed by top mold 15 and bottom mold 20 and into cavity 22 to encapsulate components 12. In this example, components 12 are shown coupled to leadframe 11. In a particular embodiment, cavity 22 may also include vent channels 44.

Prior to mold compound 21 being transferred into the mold, it is common for the mold compound to be pre-heated. The pre-heating process improves the ability of mold compound 21 to flow through bushing 7 into and throughout the mold. However, conventional pre-heating processes may introduce air into the mold compound due to the presence of air between the mold compound and the structure of the pre-heater and due to the presence of air in the compound filler due to limitations in the palletizing process. Conventional mold compound pre-heating techniques include applying multiple temperatures to various portions of the mold compound, commonly referred to as the “beer barrel” temperature effect. Experience has indicated that a side effect of the “beer barrel” temperature profile during pre-heating is the formation of internal voids in the mold compound as the entrapped air in various portions of the mold compound merges at one or more high temperature locations within the mold compound, such as the center of the pre-heated mold compound. During pre-heating, compression may be applied to mold compound 21 in an attempt to reduce the amount of entrapped air. However, convention pre-heating and compression methods are not capable of removing substantially all of the entrapped air, thereby allowing some entrapped air to be transferred into the mold when mold compound 21 is transferred into the mold through bushing 7.

In addition to the entrapped air that is transferred into the mold after pre-heating, as mold compound 21 is pushed through the mold, air or other gases may become trapped within mold compound 21. The accumulation of the air and other gases within mold compound 21 is illustrated by entrapped air 42. Furthermore, mold compound 21 may distort during the molding process, thereby locking air between the mold and mold compound 21, forming entrapped air 42. Entrapped air 42 will flow with mold compound 21 during the molding process and finally become entrapped inside cavities 22, leading to the formation of internal voids 45 when mold compound 21 cures. Internal voids 45 can lead to wire sweep or movement of component 12 within encapsulation 13. The presence of internal voids 45 within encapsulation 13 results in unsatisfactory product quality due to reduced component reliability. Frequently, the presence of internal voids 45 within encapsulation 13 may lead to the rejection of the encapsulated component.

To remove entrapped air 42 from the mold, cavity 22 may include vent channels 44. Vent channels 44 are adapted to direct air or other gasses which may have been expelled from mold compound 21 or trapped between mold compound 21 and the edges of the mold away from cavity 22. The pressure applied to mold compound 21 through plunger 8 to push mold compound 21 through the mold may force some of entrapped air 42 out of mold compound 21 and into channels 44 where it is directed away from cavity 22. By providing vent channels 44, the amount of entrapped air 42 left in mold compound 21 during the encapsulation process may be reduced, resulting in fewer voids 45 in encapsulation 13. However, current mold systems, such as those including potblock 2 of mold portion 20 (or similar potblock configurations), utilizing vent channels 44, or similar devices, may not adequately reduce the number of internal voids 45 within encapsulations 13.

FIG. 3A illustrates a schematic view of an example distribution of voids 45 within encapsulations 13 of molded part 10 that may occur when using bottom mold 20. Encapsulations 13 containing a high number of voids 45 are represented by shaded cells 50. Unshaded cells 52 illustrate encapsulations 13 with a lower level of void 45 concentration. Encapsulations 13 of molded part 10 containing the most internal voids 45 are formed in cavities 22 associated with runners 18 located nearest to cull 14. The high concentration of encapsulations 13 with voids 45 occurring in association with runners 18 located closest to cull 14 is believed to be the result of varying flow paths of mold compound 21 within sprue channels 26 and runner channels 28.

FIG. 3B illustrates example predicted flow paths 60, 61, and 62 of mold compound 21 within bottom mold 20. The varying flow paths 60, 61, and 62 within sprue channels 26 and runner channels 28 are believed to result in the high concentration of internal voids 45 in encapsulations 13 associated with runners 18 located closest to cull 14. Flow paths 60 and 61 illustrate the flow paths of mold compound 21 nearest to the edges of sprue channels 26. Flow path 62 illustrates the flow path of mold compound 21 flowing substantially in the middle of sprue channels 26. It is believed that mold compound 21 flowing closest to the edges of sprue channels 26 (i.e. flow paths 60 and 61) contains a higher concentration of entrapped air 42 than the mold compound 21 flowing through substantially the middle of sprue channel 26 (i.e. flow path 62). Mold compound 21 in flow paths 60 and 61 will generally flow around corners 29, formed at the intersection of sprue channels 26 and runner channels 28a and 28b, and into runner channels 28a and 28b. Therefore, the highest concentration of entrapped air 42 in mold compound 21 flows into cavities 22 associated with runner channels 28a and 28b, which are positioned closest to pot 24. However, the center flow path 62 (which is generally believed to contain a lesser concentration of entrapped air 42) flows into runner channels 28c and 28d that are associated with cavities 22 located further “downstream” from pot 24. Therefore, entrapped air 42 in mold compound 21 is distributed more densely in cavities 22 located closest to pot 24, resulting in more internal voids 45 in the associated encapsulations 13, as shown in FIG. 3A.

FIG. 4A illustrates an isometric view of bottom mold 200, according to the teachings of the invention. In certain embodiments, a mold may include either bottom mold 200, top mold 215 (not shown in FIG. 4A for clarity), or both. In certain embodiments, bottom mold 200 includes a baseplate 234 having a plurality of “hollows” 212, 214, 216, 218, and 219 formed therein and bordered by edges 238. Bottom mold 200 may be made from metal or any other appropriate material. Similar to bottom mold 20 described above, bottom 200 may include cavities 212, pot 214, sprue channels 216, and runner channels 218. Bottom mold 200 may also include dummy runner channels 219. Cavities 212, pot 214, sprue channels 216, runner channels 218, and dummy runner channels 219 may each comprise a chamber, well, or other appropriate “hollow” that is adapted to receive and hold mold compound 21. Potblock 205 includes pot 214, sprue channels 216, runner channels 218, and dummy runner channels 219. Chases 202 include a plurality of interconnected cavities 212. Sprue channels 216 are adapted to provide a pathway for mold compound 21 to flow from pot 214 into runner channels 218 and dummy runner channels 219. Runner channels 218 are adapted to direct the flow of mold compound 21 into cavities 212.

As described above with reference to FIG. 3B, it is believed that runner channels 28 located closest to pot 24 of bottom mold 20 receive mold compound 21 having the highest concentration of entrapped air 42. In a certain embodiment, by positioning dummy runner channels 219 between pot 214 and runner channels 218, the portions of mold compound 21 containing high concentrations of entrapped air 42, which would normally flow into runner channels 18, will now flow into dummy runner channels 219. In other words, flow paths 60 and 61 will be directed into dummy runner channels 219, rather than into runner channels 218. Flow path 62, believed to contain a lower concentration of entrapped air 42, will be directed to runner channels 218 such that mold compound 21 flows to cavities 212, resulting in encapsulations having less entrapped air 42 than encapsulations 13 of mold portion 20.

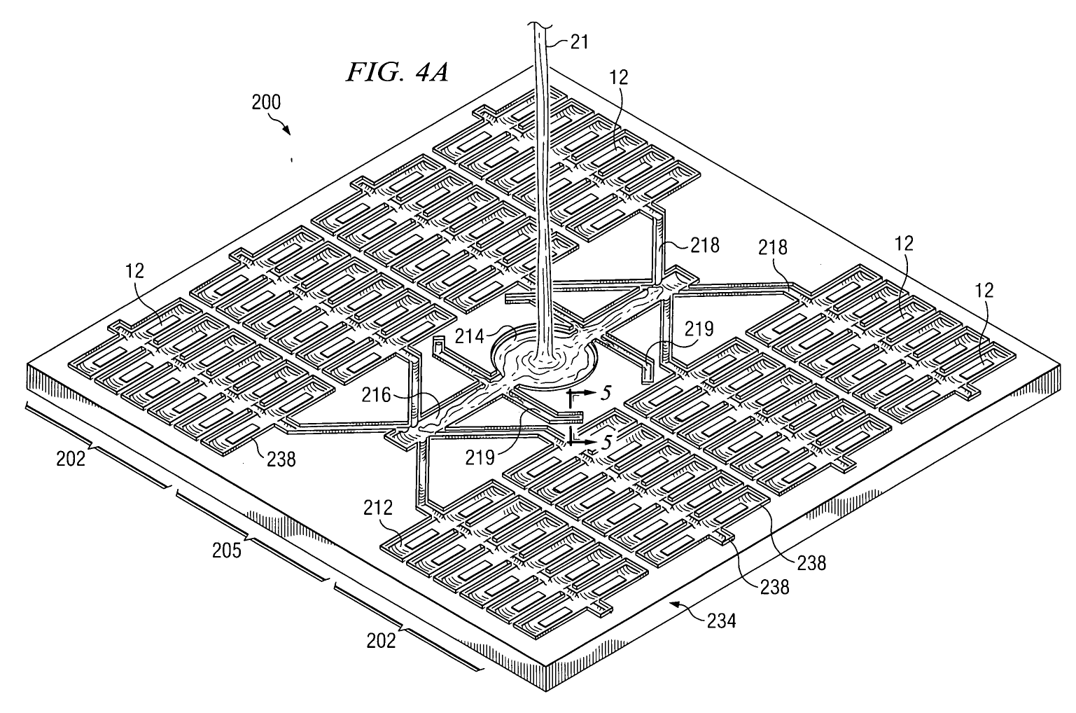

In certain embodiments, dummy runner channels 219 do not direct mold compound 21 to any cavities 212. Instead, dummy runner channels 219 include vent channels 144, described in more detail below with reference to FIG. 5, adapted to expel entrapped air 42 which may be flowing with mold compound 21. Therefore, in certain embodiments, by the time mold compound 21 reaches runner channels 218 associated with cavities 212, a larger percentage of entrapped air 42 in mold compound 21 has been removed than is removed under current mold systems, such as those including bottom mold 20, because entrapped air 42 associated with flow paths 60 and 61 has been directed into dummy runner channels 219. Therefore, less entrapped air 42 reaches cavities 212, resulting in fewer internal voids 45.

FIG. 4B illustrates a plan view of molded part 100 with dummy runners 119 formed using bottom mold 200 of FIG. 4A. Molded part 100 is formed in a similar manner to that previously described for forming molded part 10. In certain embodiments, molded part 100 includes encapsulations 113 containing components 12, cull 114, sprues 116, runners 118, and dummy runners 119. Unlike runners 18 of molded part 10 and runners 118 of molded part 100, which are coupled to encapsulations 13 and 113, respectively, in certain embodiments dummy runners 119 are not coupled to any encapsulations 113.

FIG. 5 illustrates a cross-section of an example dummy runner channel 219 cut along line 5-5 of FIG. 4A. This cross-sectional view shows top mold 215, and bottom mold 200 including dummy runner channel 219. In certain embodiments, dummy runner channels 219 include vent channels 244 which are adapted to remove entrapped air 42 which may be expelled from mold compound 21 during the molding process, thereby leaving less entrapped air 42 inside mold compound 21 as it flows through runner cavities 218 and is distributed in cavities 212 to encapsulate components 12.

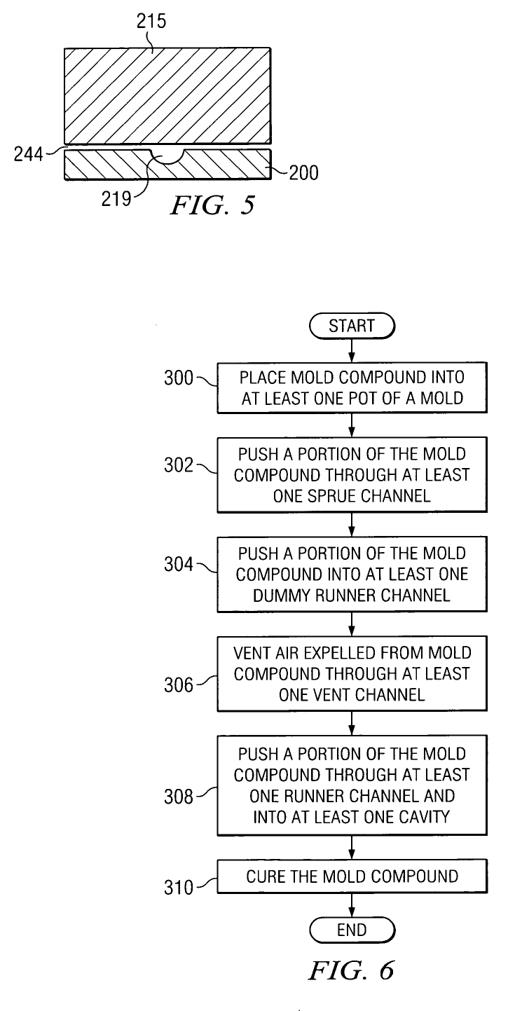

FIG. 6 illustrates an example method for forming molded part 100. The method begins at step 300 where mold compound 21 is placed into at least one pot 214 of bottom mold 200. At step 302, a portion of mold compound 21 is pushed through at least one sprue channel 216 coupled to pot 214. At step 304, a portion of mold compound 21 is pushed into at least one dummy runner channel 219 which may be coupled to at least one sprue channel 216. At step 306, the air expelled from mold compound 21 is vented through the at least one vent channel 144 coupled to dummy runner channel 219. At step 308, a portion of mold compound 21 is pushed through at least one runner channel 218 and into at least one cavity 212. Runner channel 218 may be coupled to the at least one sprue channel 216 and further coupled to cavity 212. At step 310, mold compound 21 is cured to form molded part 100.

Although an example method is illustrated, the present invention contemplates two or more steps taking place substantially simultaneously or in a different order. In addition, the present invention contemplates using methods with additional steps, fewer steps, or different steps, so long as the steps remain appropriate for forming molded part 100 comprising dummy runners 119.

Although the present invention has been described with several embodiments, a multitude of changes, substitutions, variations, alterations, and modifications may be suggested to one skilled in the art, as it is intended that the invention encompass all such changes, substitutions, variations, alterations, and modifications as fall within the spirit and scope of the appended claims.

What is claimed is:

1. A mold for forming a molded part, comprising:
a baseplate;
at least one pot formed in the baseplate for receiving a mold compound;
at least one cavity formed in the baseplate and adapted to receive a microelectronic device; and
at least one channel system formed in the baseplate and coupled to the at least one pot and further coupled to the at least one cavity;
at least one first channel formed in the baseplate and coupled to the at least one channel system and separated from the at least one cavity by the at least one channel system.

2. The mold of claim 1, wherein the channel system comprises a second channel coupled to a third channel.

3. The mold of claim 1, further comprising a microelectronic device disposed within at least one cavity.

4. The mold of claim 3, wherein the microelectronic device comprises a semiconductor device.

5. The mold of claim 3, wherein the at least one cavity is adapted to form an encapsulation of the mold compound around the microelectronic device.

6. The mold of claim 1, wherein the at least one first channel is coupled to the at least one channel system between the pot and the at least one cavity.

7. The mold of claim 1, further comprising at least one vent coupled to the at least one first channel, the at least one vent adapted to vent air expelled from the mold compound.

8. The mold of claim 1, wherein the at least one first channel is substantially perpendicularly coupled to the at least one channel system.

9. A mold for forming a molded part, comprising:
a baseplate;
at least one pot formed in the baseplate for receiving a mold compound;
at least one sprue channel formed in the baseplate and coupled to the at least one pot;
at least one cavity formed in the baseplate and adapted to receive a microelectronic device;
at least one runner channel formed in the baseplate and coupling the at least one sprue channel to the at least one cavity;
at least one dummy runner channel formed in the baseplate and coupled to the at least one sprue channel, the at least one dummy runner channel separated from the at least one cavity by the at least one sprue channel; and
at least one vent coupled to the at least one dummy runner channel, the at least one vent adapted to vent air expelled from the mold compound.

10. The mold of claim 9, further comprising a microelectronic device disposed within at least one cavity.

11. The mold of claim 10, wherein the microelectronic device comprises a semiconductor device.

12. The mold of claim 10, wherein the at least one cavity is adapted to form an encapsulation of the mold compound around the microelectronic device.

13. The mold of claim 9, wherein the at least one dummy runner channel is coupled to the at least sprue channel between the pot and the at least one cavity.

14. The mold of claim 9, further comprising at least one vent coupled to the at least dummy runner channel, the at least one vent adapted to vent air expelled from the mold compound.

15. The mold of claim 9, wherein the at least one dummy runner channel is substantially perpendicularly coupled to the sprue channel.

16. A method for forming a molded part, comprising:
placing a mold compound into at least one pot of a mold;
pushing a portion of the mold compound through at least one sprue channel coupled to the at least one pot;
pushing a portion of the mold compound into at least one dummy runner channel coupled to the at least one sprue channel runner, the at least one dummy runner channel separated from at least one cavity by the at least one sprue channel;
venting air expelled from the mold compound through at least one vent coupled to the at least dummy runner channel;
pushing a portion of the mold compound through at least one runner channel and into the least one cavity adapted to receive a microelectronic device, the at least one runner channel coupled to the at least one sprue channel and further coupled to the at least one cavity; and
curing the mold compound to form the molded part.

17. The method of claim 16, further comprising disposing a microelectronic device within the at least one cavity.

18. The method of claim 17, wherein the microelectronic device comprises a semiconductor device.

19. The method of claim 17, further comprising forming an encapsulation of the mold compound around the microelectronic device.

20. The method of claim 16, wherein the at least one dummy runner channel is coupled to the at least sprue channel between the pot and the at least one cavity.
